(19) United States
(12) Patent Application Publication
(10) Pub. No.: US 2012/0048358 A1
(43) Pub. Date: Mar. 1, 2012

(54) SOLAR CELL AND METHOD FOR MANUFACTURING THE SAME

(76) Inventors: Dong-Jin KIM, Seoul (KR); Bo-Hwan PARK, Seoul (KR); Czang-Ho LEE, Hwasung-si (KR); Joon-Young SEO, Seoul (KR)

(21) Appl. No.: 13/109,900

(22) Filed: May 17, 2011

(30) Foreign Application Priority Data
Aug. 27, 2010 (KR) 10-2010-0083423

(51) Int. Cl. H01L 31/02; H01L 31/20; H01L 31/06

(52) U.S. Cl. 136/255; 136/256; 438/96; 257/E31.045; 257/E31.049; 257/E31.062

(57) ABSTRACT

Provided are a solar cell and a method for manufacturing the same.

A solar cell according to an exemplary embodiment of the present invention includes: a substrate; a first electrode disposed on the substrate and including a first groove; a first semiconductor layer disposed on the first electrode; a second semiconductor layer disposed on the first semiconductor layer; and a second electrode disposed on the second semiconductor layer. The first semiconductor layer and the second semiconductor layer have a second groove extending therethrough, the second electrode extends into the second groove, and a third groove is formed in the second electrode and positioned within the second groove.

### CROSS-REFERENCE TO RELATED APPLICATION

This application claims priority to, and the benefit of, Korean Patent Application No. 10-2010-0083423 filed in the Korean Intellectual Property Office on Aug. 27, 2010, the entire contents of which are incorporated herein by reference.

### BACKGROUND OF THE INVENTION

(a) Field of the Invention

The present invention relates generally to solar cells. More specifically, the present invention relates to solar cells and methods for their manufacture.

(b) Description of the Related Art

Solar cells are elements that convert solar energy into electrical energy. Commonly, solar cells can be thought of as diodes configured with a PN junction and classified into various types in accordance with the material used as a light absorbing layer.

Solar cells that use silicon as the light absorbing layer may be further classified into crystalline substrate (wafer) type solar cells and thin film type (amorphous, polycrystalline) solar cells.

Additional examples of typical solar cells are a compound thin film solar cell using CIGS (CuInGaSe2) or CdTe, a III-V-group solar cell, a dye-sensitized solar cell, and an organic solar cell.

Since the thin film solar cell has uniform open circuit voltage (Voc) regardless of its size, patterning is performed so that unit cells are connected in series, so as to generate the desired voltage when a solar cell module is manufactured.

However, if a semiconductor layer is damaged and a residual film is generated at the side of the semiconductor layer, pattern faults may be generated in the process of patterning, and efficiency of the solar cell may be reduced. This is especially problematic when cells are connected in series, as a fault in one may affect other cells in the series.

The above information disclosed in this Background section is only for enhancement of understanding of the background of the invention and therefore it may contain information that does not form the prior art that is already known in this country to a person of ordinary skill in the art.

### SUMMARY OF THE INVENTION

Embodiments of the invention provide a solar cell having the advantage of preventing damage to a semiconductor layer during patterning, and a method for manufacturing the solar cell.

An exemplary embodiment of the present invention provides a solar cell that includes: a substrate; a first electrode disposed on the substrate and including a first groove; a first semiconductor layer disposed on the first electrode; a second semiconductor layer disposed on the first semiconductor layer; and a second electrode disposed on the second semiconductor layer. The first semiconductor layer and the second semiconductor layer have a second groove extending therethrough, the second electrode extends into the second groove. A third groove is formed in the second electrode and is positioned within the second groove.

A portion of a lateral surface of the first semiconductor layer may have an insulating region exposed by the third groove.

An upper end of the lateral surface of the first semiconductor layer has a generally inclined shape contacting the second groove, and the insulating region may extend generally from the upper end of the lateral surface of the first semiconductor layer.

The second semiconductor layer may include germanium (Ge).

A lower end of the second groove may generally have a “U” shape at least partially formed by an upper surface of the first electrode.

The first semiconductor layer may include a first P-layer, a first I-layer which is made of amorphous silicon, and a first N-layer, and the second semiconductor layer may include a second P-layer, a second I-layer which is made of amorphous silicon germanium (a-SiGe), and a second N-layer.

The solar cell may further include a third semiconductor layer disposed between the second semiconductor layer and the second electrode. Also, the second groove may extend through the first semiconductor layer, the second semiconductor layer, and the third semiconductor layer.

The third semiconductor layer may include a third P-layer, a third I-layer which is made of micro crystalline silicon (mc-Si:H), and a third N-layer.

Another exemplary embodiment of the present invention provides a method for manufacturing a solar cell, which includes: forming a first electrode on a substrate; forming a first groove by patterning the first electrode; and sequentially forming a first semiconductor layer and a second semiconductor layer on the first electrode. Also included is forming a second groove extending through the first semiconductor layer and the second semiconductor layer; forming a second electrode disposed on the second semiconductor layer and extending into the second groove; and forming a third groove in the second groove. The third groove exposes a portion of a lateral surface of the first semiconductor layer, where the lateral surface of the first semiconductor layer is also in contact with the second groove.

The forming a second groove may further include radiating a laser having a laser output beam with a Gaussian pattern.

The forming a second groove may further include radiating a laser having a wavelength in the range of about 1020 nm to about 1080 nm.

The forming a second groove may further include radiating a laser having an output in the range of about 3 W to about 5 W.

The forming a second groove may further include radiating a laser in a direction generally inclined with respect to the substrate.

The forming a third groove may further include radiating a laser having a wavelength in the range of about 500 nm to about 600 nm.

The forming a second groove may further include, before the forming a second groove, forming a third semiconductor layer on the second semiconductor layer, and the forming a second groove may further include forming the second groove to pass through the first semiconductor layer, the second semiconductor layer, and the third semiconductor layer.

Yet another exemplary embodiment of the present invention provides a solar cell that includes: a substrate; a first electrode disposed on the substrate and including a first groove; a P-layer disposed on the first electrode; an I-layer disposed on the P-layer; an N-layer disposed on the I-layer; and a second electrode disposed on the N-layer. A second groove extends through the P-layer, the I-layer, and the N-layer, wherein the second electrode extends into the second groove; and a third groove disposed in the second groove and extending through at least a portion of the second electrode.

A portion of a lateral surface of the P-layer may have an insulating region exposed by the third groove.

An upper end of the lateral surface of the P-layer has a generally inclined shape contacting the second groove, and the insulating region may extends generally from the upper end of the lateral surface of the first semiconductor layer.

The I-layer may be a light absorbing layer that includes germanium (Ge).

A lower end of the second groove may generally have a “U” shape at least partially formed by an upper surface of the first electrode.

According to the exemplary embodiments of the present invention, it is possible to increase efficiency of a solar cell by minimizing damage to a semiconductor layer in a patterning process.

### BRIEF DESCRIPTION OF THE DRAWINGS

FIG. 1 is a cross-sectional view of a solar cell according to an exemplary embodiment of the present invention.

FIG. 2 to FIG. 7 are cross-sectional views showing a method for manufacturing a solar cell according to another exemplary embodiment of the present invention.

FIG. 8 is a cross-sectional view of a solar cell according to yet another exemplary embodiment of the present invention.

FIG. 9 to FIG. 14 are cross-sectional views showing a method for manufacturing a solar cell according to still another exemplary embodiment of the present invention.

FIG. 15 is a cross-sectional view of a solar cell according to a further exemplary embodiment.

### DETAILED DESCRIPTION OF THE EMBODIMENTS

The present invention will be described more fully hereinafter with reference to the accompanying drawings, in which exemplary embodiments of the invention are shown.

As those skilled in the art would realize, the described embodiments may be modified in various different ways, all without departing from the spirit or scope of the present invention.

The exemplary embodiments that are disclosed herein are provided in order to apparent and accomplish the disclosed contents and sufficiently transmit the spirit of the present invention to a person of an ordinary skill in the art.

The size and thickness of layers and regions may be exaggerated for better comprehension and ease of description in the drawings. The upper and lower bounds of numerical ranges are approximate, and the invention is not limited to only these ranges.

In addition, in the case of when the layer is mentioned to be present “on” the other layer or substrate, it may be directly formed on the other layer or substrate or a third layer may be interposed between them.

Like reference numerals designate like components throughout the specification.

FIG. 1 is a cross-sectional view of a solar cell according to an exemplary embodiment of the present invention.

Referring to FIG. 1, a solar cell according to the exemplary embodiment of the present invention includes a first electrode 110 stacked on a substrate 100.

A first groove G1 is formed so as to pass through the first electrode 110.

The substrate 100 may be a glass substrate.

The first electrode 110 serves as a lower electrode, and may be made of SnO2, ZnO:Al, ZnO:B, ITO (Indium Tin Oxide), IZO (Indium Zinc Oxide) or the like.

The amount of light effectively absorbed by the solar cell can be increased by applying a texture on the surface of the first electrode 110 to reduce light reflection from the surface of the solar cell. To that end, a first P-layer 120 having P-type impurities, a first I-layer 130 formed of an intrinsic semiconductor, and a first N-layer 140 having N-type impurities are sequentially staked on the first electrode 110. The first I-layer 130 functions as a light absorbing layer, and provides a path for moving charge carriers from the first P-layer 120 to the first N-layer 140 by generating an electric field. That is, the first I-layer 130 absorbs sunlight, and this absorbed sunlight generates carriers, i.e. free electrons and corresponding holes, in the first I-layer 130. The electrons are collected in the first N-layer 140 and the holes are collected in the first P-layer 120 by drift of the internal electric field, thereby generating current.

The first P-layer 120 may be made of any suitable material, for example it may be made of one of amorphous silicon (Boron doped a-Si:H) doped with boron, amorphous silicon carbide (a-SiC:H), and micro crystalline silicon (mc-Si:H). The first I-layer 130 and the first N-layer 140 may each be made of amorphous silicon (a-Si:H).

In a tandem type solar cell according to the exemplary embodiment of the present invention, the first P-layer 120, the first I-layer 130, and the first N-layer 140 may collectively form a first semiconductor layer T. A second semiconductor layer B may be formed by sequentially stacking a second P-layer 160, a second I-layer 170, and a second N-layer 180 on the first semiconductor layer T.

The second I-layer 170, which is the light absorbing layer of the second semiconductor layer B, may be made of amorphous silicon germanium (a-SiGe).

In general, an amorphous silicon layer is used for a doping layer adjacent to light absorbing layers made of amorphous silicon, and a micro crystalline silicon layer is used for a doping layer adjacent to light absorbing layers made of micro crystalline silicon. Therefore, the second N-layer 180 of the second semiconductor layer B may be made of amorphous silicon germanium (a-SiGe).

In the tandem type solar cell structure, an intermediate layer (not shown) may be formed between the first semiconductor layer T and the second semiconductor layer B, in order to increase the cell's efficiency.

The first semiconductor layer T and the second semiconductor layer B have a second groove G2 passing through the semiconductor layers.

A second electrode 200 is disposed on the second semiconductor layer B, so that the majority of second groove G2 is filled with the second electrode 200. A third groove G3 passes through a portion of the second groove G2. That is, second groove G2 has a third groove G3 within it, the third groove G3 being formed by removing a portion of second electrode 200. The third groove G3 has a width smaller than the second groove G2, and is disposed within the region where the second groove G2 is formed.

From FIG. 1, it can be seen that the lower surface of the second groove G2 has a “U” shape (although any other suitable shape is contemplated). Accordingly, the first semiconductor layer T has an inclined lateral surface where it contacts the second electrode 200. Further, insulating region A, extending from the inclined lateral surface of the first semiconductor layer T, is exposed by third groove G3. That is, second electrode 200 leaves a portion of the first I-layer 130 exposed, i.e. not connected to a conductor, thus forming insulating region A.

The insulating region A allows the carriers (holes or electrons) to move along a first path C1, a second path C2, and a third path C3, in the solar cell structure according to the exemplary embodiment of the present invention. In particular, as shown in FIG. 1, the rightmost portion of second electrode 200 is separated from the first electrode 110 by an insulating region A, preventing a short and allowing carriers to move along third path C3 instead of directly into second electrode 200 from first electrode 110.

In particular, it is possible to prevent a short circuit from being generated between the first electrode 110 and the second electrode 200, in the third path C3.

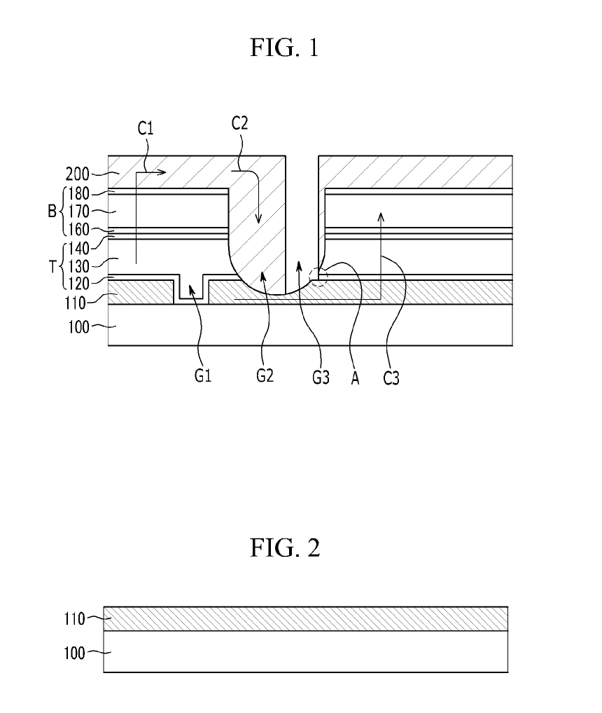

FIG. 2 to FIG. 7 are cross-sectional views showing a method for manufacturing the solar cell of FIG. 1.

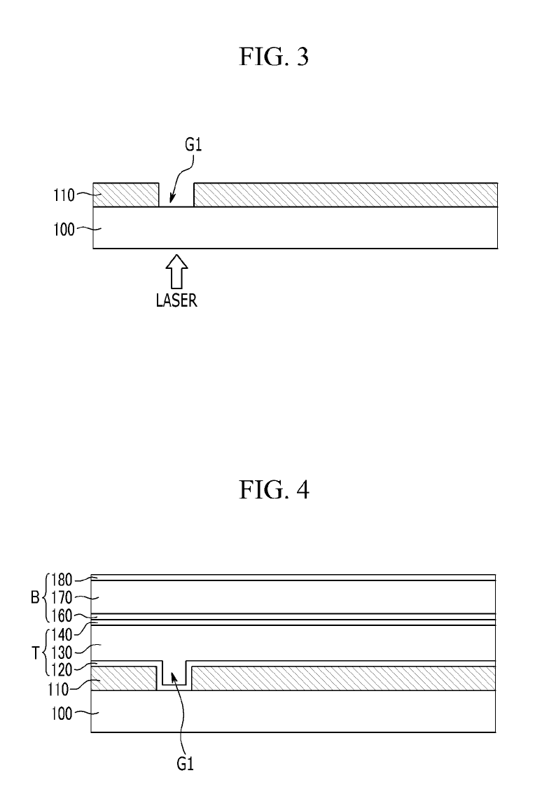

Referring to FIG. 2 and FIG. 3, the first groove G1 is formed by depositing and patterning the first electrode 110 on the substrate 100. In this case, the patterning may be performed by using laser having a wavelength of approximately 340 nm to 370 nm, or 1020 nm to 1080 nm. More specifically, the laser may preferably have a wavelength of approximately 355 nm, or 1060 nm to 1064 nm.

Referring to FIG. 4, the first semiconductor layer T is then formed. In particular, the first P-layer 120, the first I-layer 130, and the first N-layer 140 are formed in reverse order. The first P-layer 120, the first I-layer 130, and the first N-layer 140 may be deposited by plasma chemical vapor deposition (PECVD).

The second semiconductor layer B is formed next, by forming the second P-layer 160, the second I-layer 170, and the second N-layer 180 in reverse order.

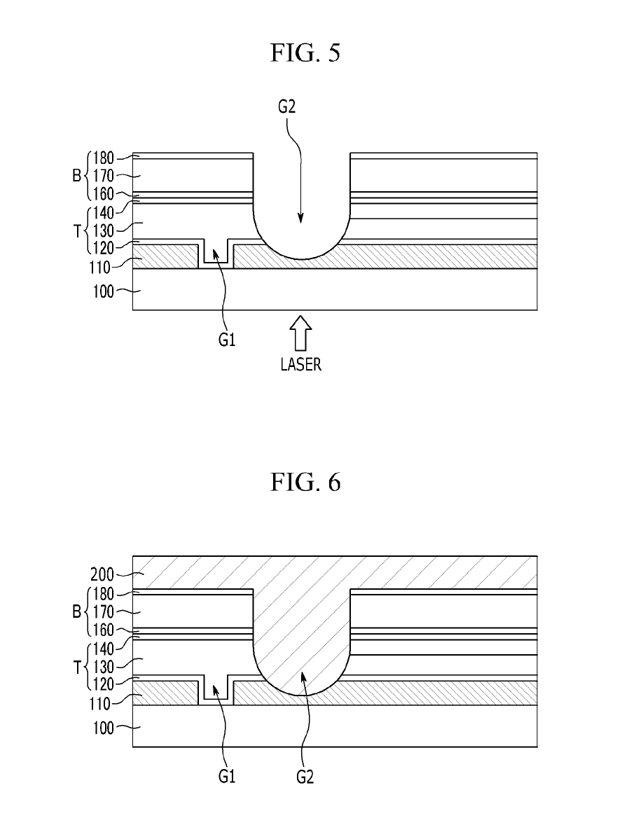

Referring to FIG. 5, the second groove G2 is formed in layers 110 through 180, so as to pass through the first semiconductor layer T and the second semiconductor layer B. The lower surface of the second groove G2 may be patterned to have a “U” shape. In particular, the lower lateral surface of the first semiconductor layer T may have an inclined profile.

A laser having a laser output beam with a Gaussian pattern may be used to form the second groove G2. In this case, a portion of the upper surface of the first electrode 110 may be hollowed out. The laser used for forming the second groove G2 may have a wavelength of approximately 1020 nm to 1080 nm. More specifically, the laser may preferably have a wavelength of about 1060 nm to 1064 nm. Further, the output range of the laser may be approximately 3 W to 5 W.

As another exemplary embodiment of the present invention, the second groove G2 may be formed by radiating a laser in the inclined direction with respect to the substrate 100. In particular, the process margin for making the side of the thin film inclined may be increased by radiating the laser in the inclined direction with respect to the substrate 100.

Referring to FIG. 6, the second electrode 200 is formed on the second semiconductor layer B to fill the second groove G2.

As the second electrode 200 fills the second groove G2, it directly contacts the inclined lateral surface of the first semiconductor layer T.

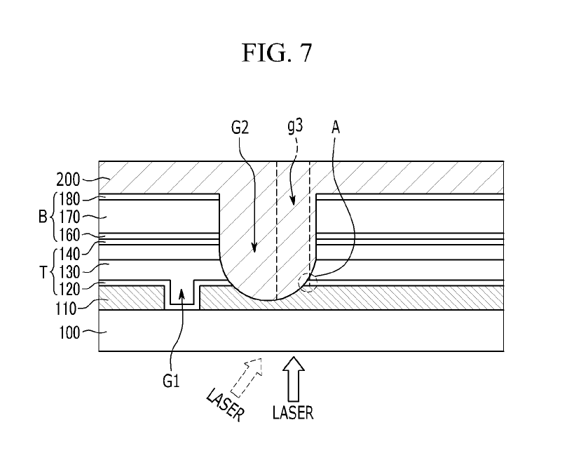

Referring to FIG. 7, the third groove G3 is formed by radiating a laser upon a reserved-pattern region g3 that is positioned in the second groove G2. The laser used for forming the third groove G3 may have a wavelength within the range of approximately 500 nm to 600 nm. Particularly, a green laser of about 532 nm may be used.

The third groove G3 is positioned and sized so as to expose a portion A of the lateral surface of the first semiconductor layer T.

In detail, the second groove G2 is formed with a curved bottom portion, which imparts an inclined profile to a portion of the first semiconductor layer T. One side of this inclined profile is then covered with second electrode 200.

When the portion of the lateral surface of the first semiconductor layer T which is exposed by the third groove G3 is an insulating region A, the insulating region A extends from the upper end of the lateral surface of the first semiconductor layer T.

When a solar cell is manufactured by a method of manufacturing a solar cell according to the exemplary embodiment of the present invention, it is possible to prevent the semiconductor layer from being damaged by high temperature in the patterning process.

In particular, laser processes that remove layers also direct energy into layer-layer interfaces or layers themselves. In FIG. 5 for instance, in the laser shown would direct energy into layer 110. The resulting temperature of the surrounding area would be determined at least partly by the laser pulse width. Long pulse lasers (including normal nano-second pulses), which are usually used in thin photovoltaic laser processes, can induce high temperatures. Conversely, short pulse lasers (including pico-second and short nano-second pulses) can reduce or largely prevent a rise in temperature.

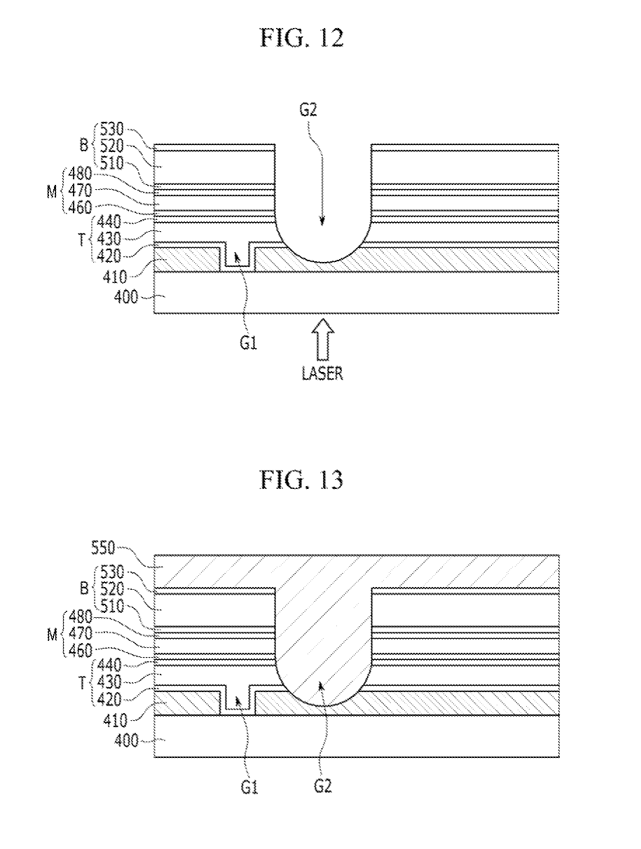

Particularly, in a semiconductor layer including germanium (Ge), leakage current is generated by diffusion phenomenon of germanium due to high temperatures induced during the laser process, such that the film is significantly damaged. For example, conventional processes often employ a second groove process which can induce thermal damage on layers including Ge. But in embodiments of the present invention, Ge-thermal damage can be largely prevented, such as by use of structures like that of FIG. 12. In FIG. 12, a laser may impose thermal damage on layers 410, 420, 430 and 440, depending on conditions. In contrast, the layers including Ge—460, 470, 480, 510, 520, 530—would remain largely undamaged.

However, according to the exemplary embodiment of the present invention, it is possible to largely prevent the second semiconductor layer B including germanium (Ge) from being damaged by the laser. This is accomplished by using a laser having a wavelength of about 1060 nm to about 1064 nm, a relatively short pulse width under about 10̂(−9) nm, and output of about 3 W to about 5 W smaller than that typically used in the process of patterning semiconductor layers including germanium (Ge.

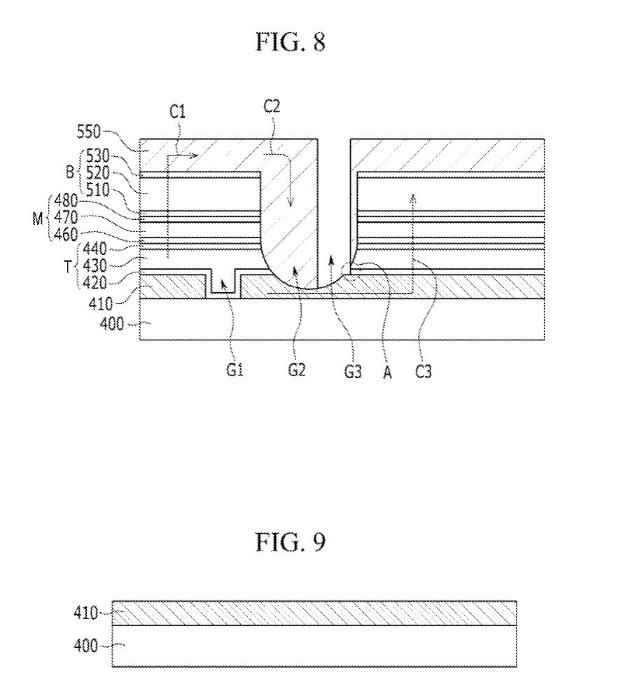

FIG. 8 is a cross-sectional view of a solar cell according to yet another exemplary embodiment of the present invention.

Referring to FIG. 8, a solar cell according to the exemplary embodiment of the present invention includes a first electrode 410 stacked on a substrate 400.

A first groove G1 passing through the first electrode 410 is formed.

The substrate 400 may be a glass substrate.

The first electrode 410 serves as a lower electrode and may be made of SnO2, ZnO:Al, ZnO:B, ITO (Indium Tin Oxide), IZO (Indium Zinc Oxide), or the like.

The amount of light absorbed by the solar cell can be increased by applying a texture on the surface of the first electrode 410 to reduce light reflection from the surface of the solar cell. Thus, a first P-layer 420 having P-type impurities, a first I-layer 430 formed of an intrinsic semiconductor, and a first N-layer 440 having N-type impurities are sequentially staked on the first electrode 410.

The first I-layer 430 functions as a light absorbing layer, and provides a path for moving carriers from the first P-layer 420 to the first N-layer 440 by generating an electric field. That is, the first I-layer 430 absorbs sunlight, which generates carriers therein. The carriers' electrons are collected in the first N-layer 440 and the carriers' holes are collected in the first P-layer 420 by drift of the internal electric field, thereby generating current.

The first P-layer 420 may be made of any suitable material, such as one of amorphous silicon (Boron doped a-Si:H) doped with boron, amorphous silicon carbide (a-SiC:H), and micro crystalline silicon (mc-Si:H).

The first I-layer 130 and the first N-layer 140 may each be made of amorphous silicon (a-Si:H).

In a triple type solar cell according to the exemplary embodiment of the present invention, the first P-layer 420, the first I-layer 430, and the first N-layer 440 may collectively form a first semiconductor layer T.

A second semiconductor layer M may be formed by sequentially stacking a second P-layer 460, a second I-layer 470, a second N-layer 480 on the first semiconductor layer T.

The second I-layer 470, which is the light absorbing layer of the second semiconductor layer M, may be made of any suitable material, such as amorphous silicon germanium (a-SiGe).

In general, an amorphous silicon layer is used for a doping layer adjacent to light absorbing layers made of amorphous silicon, and a micro crystalline silicon layer is used for a doping layer adjacent to light absorbing layers made of micro crystalline silicon. Therefore, the second N-layer 480 of the second semiconductor layer M may be made of amorphous silicon germanium (a-SiGe).

Further, a third semiconductor layer B may be formed by sequentially stacking a third P-layer 510, a third I-layer 520, and a third N-layer 530 on the second semiconductor layer M.

The third I-layer 520, which is the light absorbing layer of the third semiconductor layer B, may be made of micro crystalline silicon (mc-Si:H).

The third P-layer 510 forms the interface with the second N-layer 480 of the second semiconductor layer M, and may be made of amorphous silicon carbide (a-SiC:H).

In this “triple type” solar cell structure, an intermediate layer (not shown) may be formed between the first semiconductor layer T and the second semiconductor layer M, or the second semiconductor layer M and the third semiconductor layer B, in order to increase cell efficiency.

The first semiconductor layer T, the second semiconductor layer M, and the third semiconductor layer B have a second groove G2 passing therethrough.

A second electrode 550 is positioned on the third semiconductor layer B, so that the majority of second groove G2 is filled with the second electrode 550.

A third groove G3 passes through a portion of the second groove G2. That is, second groove G2 has a third groove G3 within it, the third groove G3 being formed by removing a portion of second electrode 550. The third groove G3 has a width smaller than the second groove G2, and is positioned in the region where the second groove G2 is formed. The lower surface of the second groove G2 may have a “U” shape (although any other suitable shape is contemplated). Accordingly, the first semiconductor layer T has an inclined lateral surface where it contacts the second electrode 550.

Further, insulating region A, extending from the inclined lateral surface of the first semiconductor layer T, is exposed by third groove G3.

The insulating region A allows the carriers (holes or electrons) to move along a first path C1, a second path C2, and a third path C3, in the solar cell structure according to the exemplary embodiment of the present invention.

In particular, it is possible to prevent a short circuit from being generated between the first electrode 410 and the second electrode 550, in the third path C3.

FIG. 9 to FIG. 14 are cross-sectional views showing a method for manufacturing a solar cell according to still another exemplary embodiment of the present invention.

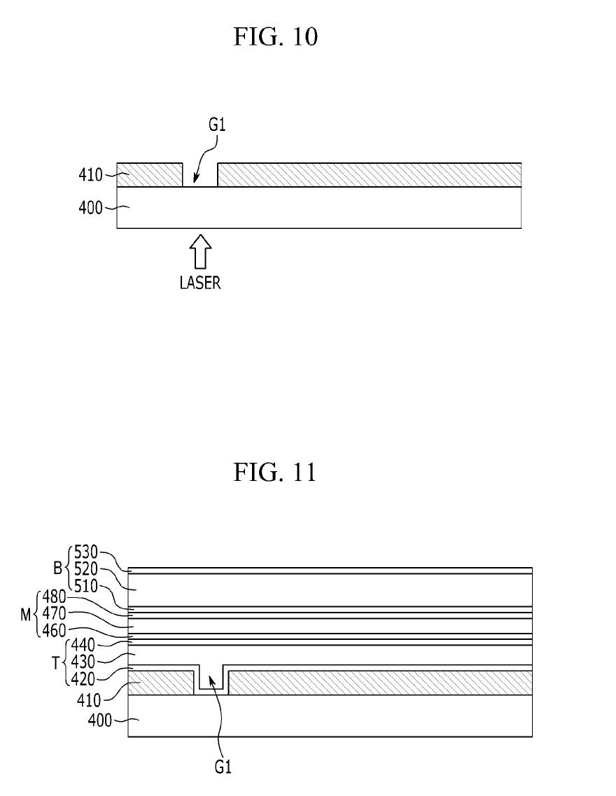

Referring to FIG. 9 and FIG. 10, the first groove G1 is formed by depositing and patterning the first electrode 410 on the substrate 400. In this case, the patterning may be performed by using laser having a wavelength of about 340 nm to 370 nm or 1020 nm to 1080 nm. The laser may preferably have a wavelength of approximately 355 nm, or about 1060 nm to 1064 nm.

Referring to FIG. 11, the first semiconductor layer T (i.e., the first P-layer 420, the first I-layer 430, and the first N-layer 440) are then formed. The first P-layer 420, the first I-layer 430, and the first N-layer 440 may be deposited by plasma chemical vapor deposition (PECVD).

The second semiconductor layer M (i.e., the second P-layer 460, the second I-layer 470, and the second N-layer 480) is then formed.

A third semiconductor layer B (including a third P-layer 510, a third I-layer 520, and a third N-layer 530) whis formed next.

Referring to FIG. 12, the second groove G2 is formed to pass through the first semiconductor layer T, the second semiconductor layer M, and the third semiconductor layer B. The lower surface of the second groove G2 may be patterned to have a “U” shape. Particularly, the lower lateral surface of the first semiconductor layer T may have has an inclined profile, such as that shown.

A laser having a laser output beam with a Gaussian pattern may be used to form the second groove G2.

In this case, a portion of the upper surface of the first electrode 410 may be hollowed out. The laser used for forming the second groove G2 may have a wavelength of about 1020 nm to 1080 nm. More specifically, the laser may preferably have a wavelength of about 1060 nm to 1064 nm. Further, the output range of the laser may be approximately 3 W to 5 W.

As another exemplary embodiment of the present invention, the second groove G2 may be formed by radiating a laser in the inclined direction with respect to the substrate 400. In particular, the process margin for making the lateral surface of the thin film inclined may be increased by radiating the laser in the inclined direction with respect to the substrate 400.

Referring to FIG. 13, the second electrode 550 is formed on the second semiconductor layer M to fill the second groove G2.

As the second electrode 550 fills the second groove G2, it directly contacts the inclined lateral surface of the first semiconductor layer T.

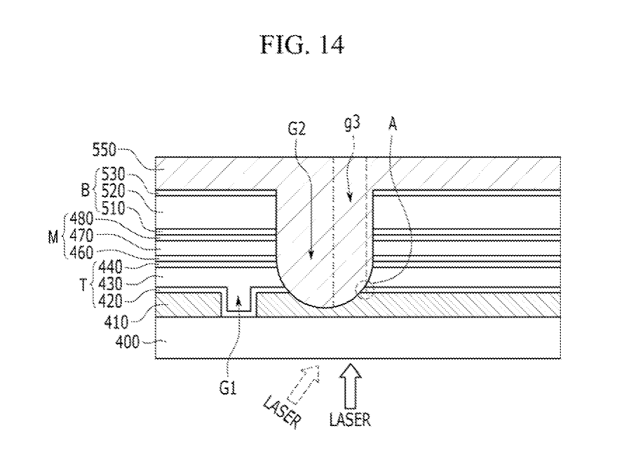

Referring to FIG. 14, the third groove G3 is formed by radiating a laser upon a reserved-pattern region g3 that is positioned in the second groove G2. The laser used for forming the third groove G3 may have a wavelength within the range of about 500 nm to 600 nm. Particularly, a green laser of approximately 532 nm may be used.

The third groove G3 is positioned and sized so as to expose a portion A of the lateral surface of the first semiconductor layer T.

In detail, the second groove G2 is formed with a curved bottom portion, which imparts an inclined profile to a portion of the first semiconductor layer T. One side of this inclined profile is then covered with second electrode 550.

When portion of the lateral surface of the first semiconductor layer T which is exposed by the third groove G3 is an insulating region A, the insulating region A extends from the upper end of the lateral surface of the first semiconductor layer T.

In the triple type solar cell according to the exemplary embodiment of the present invention, which is described above, similar to the tandem type solar cell, it is possible to prevent the second semiconductor B including germanium (Ge) from being damaged by the laser.

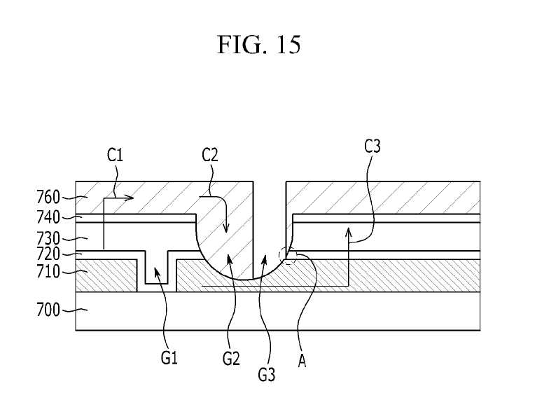

FIG. 15 is a cross-sectional view of a solar cell according to still yet another exemplary embodiment of the present invention.

Referring to FIG. 15, a solar cell according to the exemplary embodiment of the present invention includes a first electrode 710 stacked on a substrate 700.

A first groove G1 passing through the first electrode 710 is formed.

The substrate 700 may be a glass substrate.

The first electrode 710 serves as a lower electrode and may be made of SnO2, ZnO:Al, ZnO:B, ITO (Indium Tin Oxide), IZO (Indium Zinc Oxide) or the like.

A P-layer 720 having P-type impurities, an I-layer 730 formed of an intrinsic semiconductor, and an N-layer 740 having N-type impurities are then sequentially staked on the first electrode 710.

The I-layer 730 functions as a light absorbing layer, and provides a path for moving carriers from the P-layer 720 to the N-layer 740 by generating an electric field. That is, the I-layer 730 absorbs sunlight, which generates carriers within. The carriers' electrons are collected in the N-layer 740 and the carriers' holes are collected in the P-layer 720 by drift of the internal electric field, thereby generating current.

The I-layer 730 may be made of amorphous silicon germanium (a-SiGe). Further, the P-layer 720 and the N-layer 740 may be each made of any suitable material, such as one of amorphous silicon (Boron doped a-Si:H), amorphous silicon carbide (a-SiC:H), amorphous silicon germanium (a-SiGe), and a micro crystalline silicon (mc-Si:H).

The P-layer 720, the I-layer 730, and the N-layer 740 have a second groove G2 passing through the layers. A second electrode 760 is positioned on the N-layer 740, so that the majority of second groove G2 is filled with the second electrode 760.

A third groove G3 passes through a portion of the second groove G2. Thus, as in previous embodiments, second groove G2 has a third groove G3 within it, the third groove G3 being formed by removing a portion of second electrode 200.

The third groove G3 has a width smaller than the second groove G2, and is positioned in the region where the second groove G2 is formed. The lower surface of the second groove G2 may have a “U” shape, or any other shape that allows the second electrode 760 to contact first electrode 710. Accordingly, the P-layer 720 has an inclined lateral surface where it contacts the second electrode 760.

Further, insulating region A, extending from the inclined lateral surface of the P-layer 720, is exposed by third groove G3.

The insulating region A allows the carriers (holes or electrons) to move along a first path C1, a second path C2, and a third path C3, in the solar cell structure according to the exemplary embodiment of the present invention.

In particular, it is possible to prevent a short circuit from being generated between the first electrode 710 and the second electrode 760, in the third path C3.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

<Description of symbols>

| | | | |
|---|---|---|---|
| 100, 400, 700 | Substrate | 110, 410, 710 | First electrode |
| G1, G2, G3 | First to third groove | | |
| 200, 550, 760 | Second electrode | | |

What is claimed is:

1. A solar cell comprising:
a substrate;
a first electrode disposed on the substrate and including a first groove;
a first semiconductor layer disposed on the first electrode;
a second semiconductor layer disposed on the first semiconductor layer; and
a second electrode disposed on the second semiconductor layer,
wherein the first semiconductor layer and the second semiconductor layer have a second groove extending therethrough, and the second electrode extends into the second groove, and
a third groove formed in the second electrode and positioned within the second groove.

2. The solar cell of claim 1, wherein:
a portion of a lateral surface of the first semiconductor layer has an insulating region exposed by the third groove.

3. The solar cell of claim 2, wherein:
an upper end of the lateral surface of the first semiconductor layer has a generally inclined shape contacting the second groove, and the insulating region extends generally from the upper end of the lateral surface of the first semiconductor layer.

4. The solar cell of claim 3, wherein:
the second semiconductor layer includes germanium (Ge).

5. The solar cell of claim 4, wherein:
a lower end of the second groove generally has a “U” shape at least partially formed by an upper surface of the first electrode.

6. The solar cell of claim 5, wherein:
the first semiconductor layer includes a first P-layer, a first I-layer which is made of amorphous silicon, and a first N-layer, and the second semiconductor layer includes a second P-layer, a second I-layer which is made of amorphous silicon germanium (a-SiGe), and a second N-layer.

7. The solar cell of claim 1, further comprising:
a third semiconductor layer disposed between the second semiconductor layer and the second electrode,
wherein the second groove extends through the first semiconductor layer, the second semiconductor layer, and the third semiconductor layer.

8. The solar cell of claim 7, wherein:
the third semiconductor layer includes a third P-layer, a third I-layer which is made of micro crystalline silicon (mc-Si:H), and a third N-layer.

9. A method for manufacturing a solar cell, comprising:
forming a first electrode on a substrate;
forming a first groove by patterning the first electrode;
sequentially forming a first semiconductor layer and a second semiconductor layer on the first electrode;
forming a second groove extending through the first semiconductor layer and the second semiconductor layer;
forming a second electrode disposed on the second semiconductor layer and extending into the second groove; and
forming a third groove in the second groove,
wherein the third groove exposes a portion of a lateral surface of the first semiconductor layer, wherein the lateral surface of the first semiconductor layer is also in contact with the second groove.

10. The method of claim 9, wherein:
the forming a second groove further includes radiating a laser having a laser output beam with a Gaussian pattern.

11. The method of claim 10, wherein:
the forming a second groove further includes radiating a laser having a wavelength in the range of about 1020 nm to about 1080 nm.

12. The method of claim 11, wherein:
the forming a second groove further includes radiating a laser having an output in the range of about 3 W to about 5 W.

13. The method of claim 12, wherein:
the forming a second groove further includes radiating a laser in a direction generally inclined with respect to the substrate.

14. The method of claim 13, wherein:
the forming a third groove further includes radiating a laser having a wavelength in the range of about 500 nm to about 600 nm.

15. The method of claim 9, wherein:
the forming a second groove further includes, before the forming a second groove, forming a third semiconductor layer on the second semiconductor layer, and;
the forming a second groove further includes forming the second groove to pass through the first semiconductor layer, the second semiconductor layer, and the third semiconductor layer.

16. A solar cell comprising:
a substrate,
a first electrode disposed on the substrate and including a first groove;
a P-layer disposed on the first electrode;
an I-layer disposed on the P-layer;
an N-layer disposed on the I-layer;
a second electrode disposed on the N-layer;
a second groove extending through the P-layer, the I-layer, and the N-layer, wherein the second electrode extends into the second groove; and
a third groove disposed in the second groove and extending through at least a portion of the second electrode.

17. The solar cell of claim 16, wherein:
a portion of a lateral surface of the P-layer has an insulating region exposed by the third groove.

18. The solar cell of claim 17, wherein:
an upper end of the lateral surface of the P-layer has a generally inclined shape contacting the second groove, and the insulating region extends generally from the upper end of the lateral surface of the first semiconductor layer.

19. The solar cell of claim 18, wherein:
the I-layer is a light absorbing layer that includes germanium (Ge).

20. The solar cell of claim 19, wherein:
a lower end of the second groove generally has a “U” shape at least partially formed by an upper surface of the first electrode.
